(19) United States
(12) Patent Application Publication
(10) Pub. No.: US 2009/0023241 A1
(43) Pub. Date: Jan. 22, 2009

(54) CLEAN RATE IMPROVEMENT BY PRESSURE CONTROLLED REMOTE PLASMA SOURCE

(76) Inventors: Gaku Furuta, Sunnyvale, CA (US); Liwei Li, Sunnyvale, CA (US); Takao Hashimoto, Kobe-Shi (JP); Soo Young Choi, Fremont, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 12/174,408

(22) Filed: Jul. 16, 2008

Related U.S. Application Data
(60) Provisional application No. 60/950,305, filed on Jul. 17, 2007.

(51) Int. Cl. H01L 21/20; H05H 1/00

(52) U.S. Cl. 438/57; 134/1.1; 257/E21.09

(57) ABSTRACT

The present invention generally comprises a method for cleaning a large area substrate processing chamber. As chamber volume increases, it has surprisingly been found that simply scaling up the cleaning conditions may not effectively clean silicon from the exposed chamber surfaces. Undesired silicon deposits on exposed chamber surfaces may lead to contamination in solar panel formation. Increasing the pressure of the chamber to about 10 Torr or greater while maintaining the chamber at a temperature between about 150 degrees Celsius and 250 degrees Celsius increases plasma cleaning effectiveness such that silicon deposits are removed from the chamber. The combination of high pressure and low temperature may reduce substrate contamination without sacrificing substrate throughput in solar panel fabrication.

### CROSS-REFERENCE TO RELATED APPLICATIONS

This application claims benefit of U.S. Provisional Patent Application Ser. No. 60/950,305 (APPM/012076L), filed Jul. 17, 2007, which is herein incorporated by reference.

### BACKGROUND OF THE INVENTION

1. Field of the Invention

Embodiments of the present invention generally relate to a process for cleaning large area substrate processing chambers such as plasma enhanced chemical vapor deposition (PECVD) chambers.

2. Description of the Related Art

In solar panel fabrication, the demand for increased solar panel size continues to grow. Solar panels are currently being fabricated from large area substrates. With increased solar panel size and substrate size, chamber size continues to grow as well. Unfortunately, the greater the chamber size, the greater the number of areas within the chamber for silicon to deposit.

Silicon may deposit on exposed areas within the chamber during solar panel formation. If the silicon deposited on the exposed areas of the chamber is not effectively removed, the silicon may flake off and contaminate the subsequent layer to be deposited or the next substrate to be processed within the chamber. By cleaning the chamber, silicon contamination may be reduced.

Therefore, there is a need in the art for an effective cleaning method for large area substrate processing chambers.

### SUMMARY OF THE INVENTION

The present invention generally comprises a method for cleaning a large area substrate processing chamber. As chamber volume increases, it has surprisingly been found that simply scaling up the cleaning conditions may not effectively clean silicon from the exposed chamber surfaces. Undesired silicon deposits on exposed chamber surfaces may lead to contamination in solar panel formation. Increasing the pressure of the chamber to about 10 Torr or greater while maintaining the chamber at a temperature between about 150 degrees Celsius and 250 degrees Celsius increases plasma cleaning effectiveness such that silicon deposits are removed from the chamber. The combination of high pressure and low temperature may reduce substrate contamination without sacrificing substrate throughput in solar panel fabrication.

In one embodiment, a chamber cleaning method is disclosed. The method comprises flowing a cleaning gas into a remote plasma source, igniting a plasma in the remote plasma source, introducing the plasma to a processing chamber, and cleaning the chamber with the plasma. The chamber may be maintained at a pressure of about 10 Torr and above and sized to receive a substrate having a surface area of about 50,000 square centimeters or greater.

In another embodiment, a solar cell manufacturing method is disclosed. The method comprises depositing a first silicon film over a first substrate having a surface area of about 50,000 square centimeters or greater in a first chamber. The method also comprises removing the first substrate from the first chamber, cleaning the first chamber, introducing a second substrate to the first chamber, and depositing a second silicon film over the second substrate. The cleaning comprises plasma cleaning the first chamber with a cleaning gas at a pressure of about 10 Torr and above.

In another embodiment, a silicon deposition chamber cleaning method is disclosed. The method comprises introducing a cleaning gas plasma to the chamber, the chamber having a substrate receiving surface adapted to receive a substrate having a surface area of about 50,000 cm² or greater and maintained at a pressure of about 10 Torr or greater, the plasma comprising fluorine radicals, and reacting the fluorine radicals with silicon deposited on the chamber to remove the silicon.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross sectional view of a processing apparatus according to one embodiment of the invention.

FIG. 2 is a schematic view of a single junction solar cell according to one embodiment of the invention.

FIG. 3 is a schematic view of a dual tandem solar cell according to one embodiment of the invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present invention generally comprises a method for cleaning a large area substrate processing chamber. As chamber volume increases, it has surprisingly been found that simply scaling up the cleaning conditions may not effectively clean silicon from the exposed chamber surfaces. Undesired silicon deposits on exposed chamber surfaces may lead to contamination in solar panel formation. Increasing the pressure of the chamber to about 10 Torr or greater while maintaining the chamber at a temperature between about 150 degrees Celsius and 250 degrees Celsius increases plasma cleaning effectiveness such that silicon deposits are removed from the chamber. The combination of high pressure and low temperature may reduce substrate contamination without sacrificing substrate throughput in solar panel fabrication.

The invention will be illustratively described below in relation to a PECVD chamber available from AKT America, Inc., a subsidiary of Applied Materials, Inc., Santa Clara, Calif. It is to be understood that the invention is equally applicable to any chamber that may require energizing a gas into a plasma using an RF current including physical vapor deposition (PVD) chambers. It is also to be understood that the invention described below is equally applicable to PECVD chambers and other chambers made by other vendors.

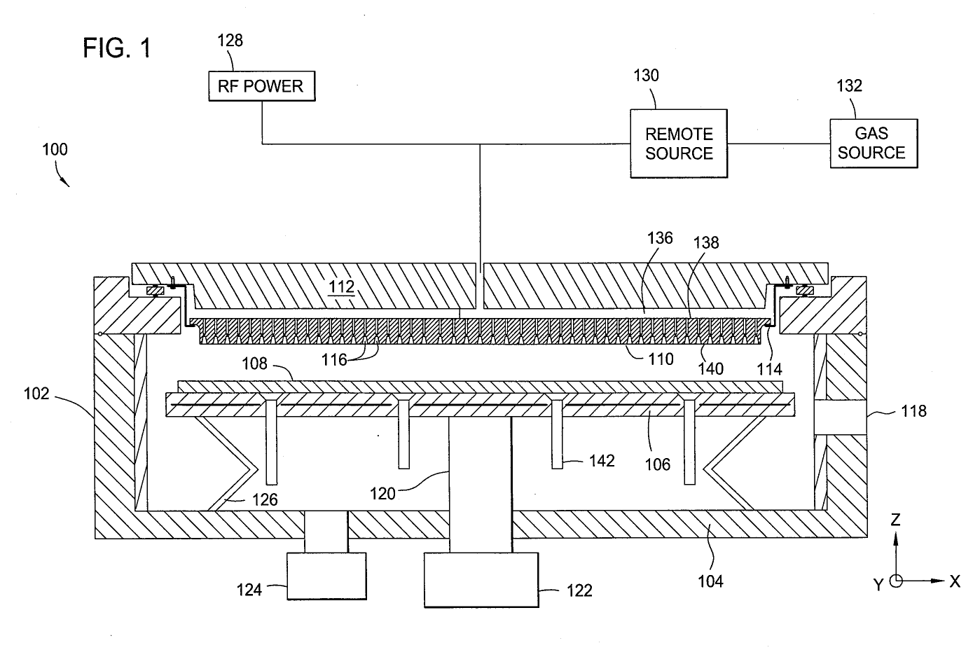

FIG. 1 is a schematic cross sectional view of a processing apparatus 100 according to one embodiment of the invention. The apparatus 100 is a PECVD chamber 102. The susceptor 106 may be grounded with grounding straps 126 coupled with the bottom 104 of the chamber 102. A substrate 108 may be disposed on the susceptor 106 and may sit opposite a showerhead 110 within the chamber 102. The showerhead 110 may be supported within the chamber 102 by a bracket 114. The substrate 108 may be inserted into the chamber 102 through a slit valve 118 and disposed onto lift pins 142. The susceptor 106 may then rise to meet the substrate 108. The susceptor 106 may be raised on a stem 120 by an actuator 122. A vacuum pump 124 may evacuate the chamber 102.

Gas may be provided to the showerhead 110 from a gas source 132. The gas may pass through a remote plasma source 130 where the gas may be energized into a plasma for cleaning purposes or simply allowed to pass therethrough to the chamber 102. The gas may be ignited into a plasma within the chamber 102 by an RF current applied from an RF power source 128. The gas is initially provided to a plenum 136 disposed between the lid 112 and the upstream side 138 of the showerhead 110. The gas may be substantially evenly distributed within the plenum and then pass through gas passages 116 in the showerhead 110 that extend between the upstream side 138 and the downstream side 140. In one embodiment, the gas passages 116 may comprise hollow cathode cavities.

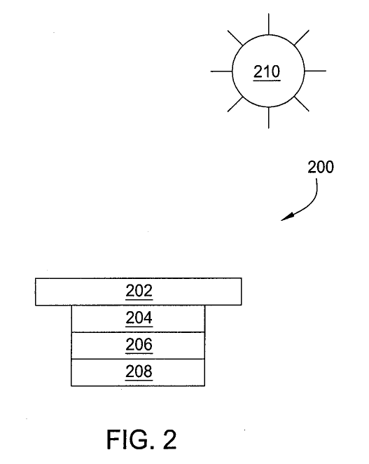

FIG. 2 is a schematic view of a single junction solar cell 200 according to one embodiment of the invention. The solar cell 200 may be formed by depositing a p-doped semiconductor layer 204, an intrinsic semiconductor layer 206, and an n-doped semiconductor layer 208 over a substrate 202. The solar cell 200, upon completion, is flipped over so that the substrate 202 faces the sun 210. The semiconductor material for the solar cell 200 may comprise silicon. In one embodiment, the silicon comprises amorphous silicon. In another embodiment, the silicon comprises microcrystalline silicon. In yet another embodiment, the silicon comprises polysilicon.

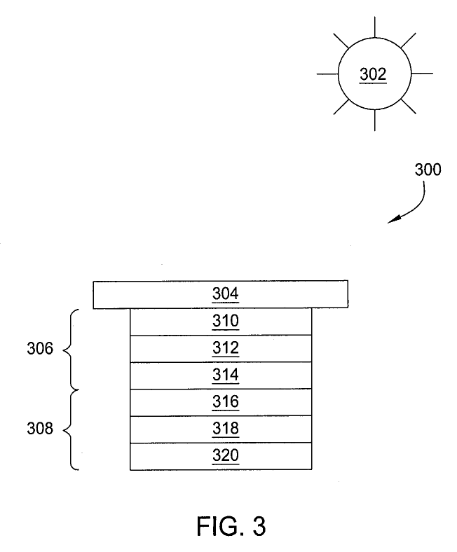

FIG. 3 is a schematic view of a dual tandem solar cell 300 according to one embodiment of the invention. The solar cell 300 may be formed by depositing a first cell 306 over a substrate 304, which would face the sun 302, and then a second cell 308 over the first cell 306. The first cell 306 may comprise a p-doped semiconductor layer 310, an intrinsic semiconductor layer 312, and an n-doped semiconductor layer 314. The second cell 308 may comprise a p-doped semiconductor layer 316, an intrinsic semiconductor layer 318, and an n-doped semiconductor layer 320.

The semiconductor material for the solar cell 300 may comprise silicon. In one embodiment, the silicon comprises amorphous silicon. In another embodiment, the silicon comprises microcrystalline silicon. In yet another embodiment, the silicon comprises polysilicon. The first cell 306 may comprise amorphous silicon as the intrinsic semiconductor layer 312 while the second cell 308 may comprise microcrystalline silicon as the intrinsic semiconductor layer 318. Thus, the solar cell 300 is a dual tandem solar cell 300 because it comprises two cells 306, 308 where each cell 306, 308 is different.

It is to be understood that while description of the invention relates to a dual tandem solar cell, the invention is equally applicable to a dual solar cell utilizing the same semiconductor material for both intrinsic semiconductor layers. Additionally, while the invention is described referring to a single junction solar cell and a dual tandem solar cell, other solar cell configurations are contemplated by the disclosure. For example, solar cells having greater than two cells are contemplated where the cells are either substantially identical or different.

To produce the solar cells, the various layers may be deposited within a common chamber or within separate chambers. In either scenario, contamination to subsequently processed substrates may be a concern. Thus, the chambers may be cleaned between each deposition. Alternatively, the chambers may be cleaned on an as needed basis.

In smaller chambers (i.e., chambers having a substrate receiving surface adapted to receive a substrate having a surface area of about 50,000 cm² or below), a plasma may be generated remotely and provided to the chamber maintained at a low pressure (ie., about 300 mTorr to about 500 mTorr). However, for larger chambers (i.e., chambers having a substrate receiving surface adapted to receive a substrate having a surface area of about 50,000 cm² or above), it has surprisingly been found that the chamber may not be effectively cleaned at 300-500 mTorr.

High pressure (i.e., about 10 Torr or greater) during the plasma cleaning may increase the residence time that the chamber components to be cleaned are exposed to the plasma. The increased residence time may reduce the amount of contaminants that remain within the chamber after cleaning because the exposed areas of the chamber are exposed to the cleaning plasma for a longer period of time. The longer that the exposed chamber components are exposed to the plasma, the greater the amount of contaminants that react with the plasma (i.e., are etched by the plasma), and are removed from the exposed chamber components. In one embodiment, the pressure may be up to about 15 Torr. In another embodiment, the pressure may be between 10 Torr and 15 Torr. The pressure of the chamber may be measured with a manometer disposed below a susceptor within the chamber.

The various layers that comprise a solar cell may be deposited at temperatures less than about 250 degrees Celsius. At temperatures greater than 250 degrees Celsius, the dopants that may comprise the p-doped semiconductor layer and the n-doped semiconductor layer may diffuse into adjacent layers such as the intrinsic semiconductor layer. When the dopants diffuse into adjacent layers, the solar cell fails. Thus, the deposition for each layer of the solar cell may be deposited at temperatures less than about 250 degrees Celsius.

To maintain a desired throughput, the cleaning may occur at temperatures equal to or less than the deposition temperature. If the temperature of the cleaning is higher than the deposition temperature, then the chamber may need to be cooled prior to disposing a substrate into the chamber for processing. The added cooling may increase the processing time and thus, decrease throughput. Similarly, if the temperature of the cleaning is lower than the deposition temperature, the chamber may need to be heated prior to disposing a substrate into the chamber for processing. It may be preferable to maintain a substantially constant deposition temperature to ensure the deposited film has substantially uniform properties throughout the layer. Thus, if the cleaning occurs at a temperature below the deposition temperature, it may be necessary to preheat the chamber prior to disposing the substrate therein. The additional heating may decrease substrate throughput.

The plasma for cleaning the chambers may be generated remotely in a remote plasma source. The plasma may comprise fluorine based etching gases such as NF₃, SF₆, F₂, and combinations thereof. Additionally, one or more additive gases may be present such as Ar, N₂O, and combinations thereof. It is preferred that O₂ gas not be provided because oxygen gas may oxidize the semiconductor material deposited on the exposed areas of the chamber and thus change the cleaning efficiency.

The power applied to the remote plasma source may be up to about 25 kW. In one embodiment, the power may be about 20 kW. The power to the remote plasma source may be a function of the gas flow rate and the pressure. In one embodiment, the fluorine based etching gas may have a flow rate of about 30 slm (i.e., standard liters per minute). The additive gases may be provided at a flow rate up to about 30 slm. The ratio of the fluorine based gas to the additive gas may be about 4:1 to about 1:1. In one embodiment, the cleaning process lasts about 60 seconds to about 120 seconds.

For large volume processing chambers (i.e., processing chambers having a substrate receiving surface adapted to receive a substrate having a surface area of about 50,000 cm² or greater), high pressures (i.e., greater than about 10 Torr) may be necessary to effectively clean the processing chamber. Surprisingly, the low pressure cleaning (i.e., about 300 mTorr to about 500 mTorr), which is sufficient for low volume processing chambers (i.e., processing chambers having a substrate receiving surface adapted to receive a substrate having a surface area of less than about 50,000 cm²), may not effectively clean the large volume processing chamber.

### EXAMPLES

### Comparison Examples 1-10

TABLE I

| Compar- | | Clean- | | | Temper- | |
|---|---|---|---|---|---|---|
| ison | Substrate | ing | Pressure | Cleaning | ature | % |
| Example | size (cm²) | gas | (mTorr) | time (sec) | (Celsius) | clean |
| 1A | 1,600 | NF₃ | 300 | 60 | 200 | >90% |
| 1B | 1,600 | NF₃ | 500 | 60 | 200 | >90% |
| 2A | 4,300 | NF₃ | 300 | 60 | 200 | >90% |
| 2B | 4,300 | NF₃ | 500 | 60 | 200 | >90% |
| 3A | 5,500 | NF₃ | 300 | 60 | 200 | >90% |
| 3B | 5,500 | NF₃ | 500 | 60 | 200 | >90% |
| 4A | 10,000 | NF₃ | 300 | 60 | 200 | >90% |
| 4B | 10,000 | NF₃ | 500 | 60 | 200 | >90% |
| 5A | 15,000 | NF₃ | 300 | 60 | 200 | >90% |
| 5B | 15,000 | NF₃ | 500 | 60 | 200 | >90% |
| 6A | 20,000 | NF₃ | 300 | 60 | 200 | >90% |
| 6B | 20,000 | NF₃ | 500 | 60 | 200 | >90% |
| 7A | 25,000 | NF₃ | 300 | 60 | 200 | >90% |
| 7B | 25,000 | NF₃ | 500 | 60 | 200 | >90% |
| 8A | 40,000 | NF₃ | 300 | 60 | 200 | >90% |
| 8B | 40,000 | NF₃ | 500 | 60 | 200 | >90% |
| 9A | 50,000 | NF₃ | 300 | 60 | 200 | >75% |
| 9B | 50,000 | NF₃ | 500 | 60 | 200 | >75% |
| 10A | 60,000 | NF₃ | 300 | 60 | 200 | >50% |
| 10B | 60,000 | NF₃ | 500 | 60 | 200 | >50% |

Table I shows results for cleaning various processing chambers at low pressure (i.e., about 300 mTorr to about 500 mTorr). For each example, the chamber was cleaned after a silicon deposition process had occurred in the chamber. The various processing chambers each have a substrate receiving surface adapted to receive substrates having the substrate size listed for each example. For each chamber, two cleaning examples are shown. The first cleaning example for each chamber (designed with an “A” such as example 1A), occurred at a chamber pressure of 300 mTorr and a chamber temperature of 200 degrees Celsius. The cleaning occurred for 60 seconds. The second cleaning example for each chamber (designed with a “B” such as example 1B), occurred at a chamber pressure of 500 mTorr and a chamber temperature of 200 degrees Celsius. The second cleaning also occurred for 60 seconds.

### Comparison Examples 1A and 1B

A processing chamber having a substrate receiving surface adapted to receive a substrate having a surface area of about 1,600 cm² was exposed to cleaning gas plasma for 60 seconds at a processing temperature of 200 degrees Celsius. In comparison example 1A, the pressure was 300 mTorr. In comparison example 1B, the pressure was 500 mTorr. In both comparison example 1A and comparison example 1B, the percentage of the processing chamber that was cleaned was greater than 90 percent such that less than 10 percent contaminants remained within the processing chamber.

### Comparison Examples 2A and 2B

A processing chamber having a substrate receiving surface adapted to receive a substrate having a surface area of about 4,300 cm² was exposed to cleaning gas plasma for 60 seconds at a processing temperature of 200 degrees Celsius. In comparison example 2A, the pressure was 300 mTorr. In comparison example 2B, the pressure was 500 mTorr. In both comparison example 2A and comparison example 2B, the percentage of the processing chamber that was cleaned was greater than 90 percent such that less than 10 percent contaminants remained within the processing chamber.

### Comparison Examples 3A and 3B

A processing chamber having a substrate receiving surface adapted to receive a substrate having a surface area of about 5,500 cm² was exposed to cleaning gas plasma for 60 seconds at a processing temperature of 200 degrees Celsius. In comparison example 3A, the pressure was 300 mTorr. In comparison example 3B, the pressure was 500 mTorr. In both comparison example 3A and comparison example 3B, the percentage of the processing chamber that was cleaned was greater than 90 percent such that less than 10 percent contaminants remained within the processing chamber.

### Comparison Examples 4A and 4B

A processing chamber having a substrate receiving surface adapted to receive a substrate having a surface area of about 10,000 cm² was exposed to cleaning gas plasma for 60 seconds at a processing temperature of 200 degrees Celsius. In comparison example 4A, the pressure was 300 mTorr. In comparison example 4B, the pressure was 500 mTorr. In both comparison example 4A and comparison example 4B, the percentage of the processing chamber that was cleaned was greater than 90 percent such that less than 10 percent contaminants remained within the processing chamber.

### Comparison Examples 5A and 5B

A processing chamber having a substrate receiving surface adapted to receive a substrate having a surface area of about 15,000 cm² was exposed to cleaning gas plasma for 60 seconds at a processing temperature of 200 degrees Celsius. In comparison example 5A, the pressure was 300 mTorr. In comparison example 5B, the pressure was 500 mTorr. In both comparison example 5A and comparison example 5B, the percentage of the processing chamber that was cleaned was greater than 90 percent such that less than 10 percent contaminants remained within the processing chamber.

### Comparison Examples 6A and 6B

A processing chamber having a substrate receiving surface adapted to receive a substrate having a surface area of about 20,000 cm² was exposed to cleaning gas plasma for 60 seconds at a processing temperature of 200 degrees Celsius. In comparison example 6A, the pressure was 300 mTorr. In comparison example 6B, the pressure was 500 mTorr. In both comparison example 6A and comparison example 6B, the percentage of the processing chamber that was cleaned was greater than 90 percent such that less than 10 percent contaminants remained within the processing chamber.

### Comparison Examples 7A and 7B

A processing chamber having a substrate receiving surface adapted to receive a substrate having a surface area of about 25,000 cm² was exposed to cleaning gas plasma for 60 seconds at a processing temperature of 200 degrees Celsius. In comparison example 7A, the pressure was 300 mTorr. In comparison example 7B, the pressure was 500 mTorr. In both comparison example 7A and comparison example 7B, the percentage of the processing chamber that was cleaned was greater than 90 percent such that less than 10 percent contaminants remained within the processing chamber.

### Comparison Examples 8A and 8B

A processing chamber having a substrate receiving surface adapted to receive a substrate having a surface area of about 40,000 cm² was exposed to cleaning gas plasma for 60 seconds at a processing temperature of 200 degrees Celsius. In comparison example 8A, the pressure was 300 mTorr. In comparison example 8B, the pressure was 500 mTorr. In both comparison example 8A and comparison example 8B, the percentage of the processing chamber that was cleaned was greater than 90 percent such that less than 10 percent contaminants remained within the processing chamber.

### Comparison Examples 9A and 9B

A processing chamber having a substrate receiving surface adapted to receive a substrate having a surface area of about 50,000 cm² was exposed to cleaning gas plasma for 60 seconds at a processing temperature of 200 degrees Celsius. In comparison example 9A, the pressure was 300 mTorr. In comparison example 9B, the pressure was 500 mTorr. In both comparison example 9A and comparison example 9B, the percentage of the processing chamber that was cleaned was only about 75 percent such that as much as 25 percent contaminants remained within the processing chamber.

### Comparison Examples 10A and 10B

A processing chamber having a substrate receiving surface adapted to receive a substrate having a surface area of about 60,000 cm² was exposed to cleaning gas plasma for 60 seconds at a processing temperature of 200 degrees Celsius. In comparison example 10A, the pressure was 300 mTorr. In comparison example 10B, the pressure was 500 mTorr. In both comparison example 10A and comparison example 10B, the percentage of the processing chamber that was cleaned was only about 50 percent such that as much as 50 percent contaminants remained within the processing chamber.

For the chambers having a substrate receiving surface adapted to receive a substrate having a surface area of less than 50,000 cm², the percentage of silicon cleaned from the chamber was greater than 90 percent. However, for the chambers having a substrate receiving surface adapted to receive a substrate having a surface area of 50,000 cm² or more, the percentage of silicon cleaned from the chamber was less than 90 percent. Thus, the cleaning conditions used to clean chambers having a substrate receiving surface adapted to receive a substrate having a surface area of less than 50,000 cm² may not be effective for cleaning chambers having a substrate receiving surface adapted to receive a substrate having a surface area of 50,000 cm² or greater.

### Examples 1-2

TABLE II

| | Substrate | Clean- | | Cleaning | Temper- | |
|---|---|---|---|---|---|---|
| | size | ing | Pressure | time | ature | % |
| Example | (cm²) | gas | (Torr) | (sec) | (Celsius) | clean |
| 1A | 50,000 | NF₃ | 10 | 60 | 200 | >90% |
| 1B | 50,000 | NF₃ | 15 | 60 | 200 | >90% |
| 2A | 60,000 | NF₃ | 10 | 60 | 200 | >90% |
| 2B | 60,000 | NF₃ | 15 | 60 | 200 | >90% |

By raising the pressure of the processing chamber having a substrate receiving surface adapted to receive a substrate having a surface area of 50,000 cm² or greater, the processing chamber may be effectively cleaned. Table II shows results for cleaning processing chambers having a substrate receiving surface adapted to receive a substrate having a surface area of 50,000 cm² or greater. For each chamber, two cleaning examples are shown. For the first cleaning example for each chamber (designed with an “A” such as example 1A), occurred at a chamber pressure of 10 Torr and a chamber temperature of 200 degrees Celsius. The cleaning occurred for 60 seconds. The second cleaning example for each chamber (designed with a “B” such as example 1B), occurred at a chamber pressure of 15 Torr and a chamber temperature of 200 degrees Celsius. The second cleaning also occurred for 60 seconds. As shown in Table II, the percentage of silicon cleaned from the chambers was greater than 90 percent.

### Examples 1A and 1B

A processing chamber having a substrate receiving surface adapted to receive a substrate having a surface area of about 50,000 cm² was exposed to cleaning gas plasma for 60 seconds at a processing temperature of 200 degrees Celsius. In example 1A, the pressure was 10 Torr. In example 1B, the pressure was 15 Torr. In both example 1A and example 1B, the percentage of the processing chamber that was cleaned was greater than 90 percent such that less than 10 percent contaminants remained within the processing chamber.

### Examples 2A and 2B

A processing chamber having a substrate receiving surface adapted to receive a substrate having a surface area of about 60,000 cm² was exposed to cleaning gas plasma for 60 seconds at a processing temperature of 200 degrees Celsius. In example 2A, the pressure was 10 Torr. In example 2B, the pressure was 15 Torr. In both example 2A and example 2B, the percentage of the processing chamber that was cleaned was greater than 90 percent such that less than 10 percent contaminants remained within the processing chamber.

In comparing the cleaning characteristics for the processing chambers having a substrate receiving surface adapted to receive a substrate having a surface area of 50,000 cm² or greater (i.e., Examples 1A, 1B, 2A, and 2B of Table II with Examples 9A, 9B, 10A, and 10B of Table I respectively), the only difference in processing conditions is the pressure. However, the processing chambers cleaned under the high pressure were more effectively cleaned. In fact, the large chambers (i.e., processing chambers having a substrate receiving surface adapted to receive a substrate having a surface area of 50,000 cm² or greater) cleaned under the high pressure conditions were cleaned as effectively as the smaller chambers (i.e., the chambers having a substrate receiving surface adapted to receive a substrate having a surface area less than 50,000 cm²) were cleaned under low pressure conditions. Thus, large area chambers may be effectively cleaned by utilizing a high pressure (i.e., about 10 Torr or greater).

While the foregoing is directed to embodiments of the present invention, other and further embodiments of the invention may be devised without departing from the basic scope thereof, and the scope thereof is determined by the claims that follow.

1. A chamber cleaning method, comprising:
flowing a cleaning gas into a remote plasma source;
igniting a plasma in the remote plasma source;
introducing the plasma to a processing chamber sized to receive a substrate having a surface area of about 50,000 square centimeters or greater, the chamber maintained at a pressure of about 10 Torr and above; and
cleaning the chamber with the plasma.

2. The method of claim 1, wherein the cleaning gas comprises NF₃.

3. The method of claim 2, wherein the cleaning gas comprises N₂O.

4. The method of claim 3, wherein a ratio of the flow of NF₃ to N₂O is between about 4:1 to about 1:1.

5. The method of claim 1, wherein the cleaning gas comprises at least one gas selected from the group consisting of NF₃, F₂, SF₆, and combinations thereof.

6. The method of claim 1, wherein the temperature of the chamber is between about 175 degrees Celsius and about 225 degrees Celsius during the cleaning.

7. The method of claim 1, wherein the pressure is between about 10 Torr and about 15 Torr.

8. A solar cell manufacturing method, comprising:
depositing a first silicon film over a first substrate in a first chamber, the substrate having a surface area of about 50,000 square centimeters or greater;
removing the first substrate from the first chamber;
cleaning the first chamber, the cleaning comprising plasma cleaning the first chamber with a cleaning gas at a pressure of about 10 Torr and above;
introducing a second substrate to the first chamber; and
depositing a second silicon film over the second substrate.

9. The method of claim 8, wherein the solar cell comprises a single junction solar cell.

10. The method of claim 8, wherein the solar cell comprises a tandem junction solar cell.

11. The method of claim 8, wherein the cleaning gas comprises NF₃.

12. The method of claim 11, wherein the cleaning gas comprises N₂O.

13. The method of claim 12, wherein a ratio of the flow of NF₃ to N₂O is between about 4:1 to about 1:1.

14. The method of claim 8, wherein the cleaning gas comprises at least one gas selected from the group consisting of NF₃, F₂, SF₆, and combinations thereof.

15. The method of claim 8, wherein the temperature of the chamber is between about 175 degrees Celsius and about 225 degrees Celsius during the cleaning.

16. The method of claim 8, wherein the pressure is between about 10 Torr and about 15 Torr.

17. A silicon deposition chamber cleaning method, comprising:
introducing a cleaning gas plasma to the chamber, the chamber having a substrate receiving surface adapted to receive a substrate having an area of about 50,000 cm² or greater and maintained at a pressure of about 10 Torr or greater, the plasma comprising fluorine radicals; and
reacting the fluorine radicals with silicon deposited on the chamber to remove the silicon.

18. The method of claim 17, wherein the chamber has a substrate receiving surface adapted to receive a substrate having an area of about 60,000 cm² or greater.

19. The method of claim 17, wherein the temperature of the chamber is between about 175 degrees Celsius and about 225 degrees Celsius during the reacting.

20. The method of claim 17, wherein the pressure is between about 10 Torr and about 15 Torr.
